(19) United States
(12) Patent Application Publication
(10) Pub. No.: US 2008/0128682 A1
(43) Pub. Date: Jun. 5, 2008

(54) Ferrodielectric Memory Device And Method For Manufacturing The Same

(75) Inventor: Byung-Eun Park, Seoul (KR)

Correspondence Address: BRUCE E. LILLING;LILLING & LILLING PLLC, P.O. BOX 560, GOLDEN BRIDGE, NY, 10526, US

(73) Assignee: University of Seoul Foundation of Industry- Academic Cooperation, Seoul (KR)

(21) Appl. No.: 11/721,568

(22) PCT Filed: May 11, 2005
(86) PCT No.: PCT/KR06/01758

§ 371 Date: Jun. 13, 2007

(30) Foreign Application Priority Data
May 11, 2005 (KR) 10-2005-0039167
Jan. 12, 2006 (KR) 10-2006-0003399
May 10, 2006 (KR) 10-2006-0041814

(51) Int. Cl. H01L 51/00; H01L 21/00

(52) U.S. Cl. 257/40; 438/3; 257/295; 257/E51.001; 257/E21.001

(57) ABSTRACT

The present invention relates to a ferrodielectric memory device and a method for manufacturing the same that provide stable memory operations by considerably enhancing characteristics of hysteresis and remanent polarization in ferrodielectrics applied to memory devices. In the present invention, PVDF having a crystal structure of β-phase is used as a ferrodielectric substance applied to the ferrodielectric memory. The PVDF membrane in accordance with the present invention has excellent hysteresis characteristics that show a polarization of about 5 μC/cm² or more at about 1V as the polarization is increased with increasing of an applied voltage in about 0 to 1V, and have another polarization of about −5 μC/cm² or less at about −1V as the polarization is decreased with decreasing of an applied voltage in about −1V.

### TECHNICAL FIELD

The present invention relates to a memory device using ferroelectrics and a method for manufacturing the same.

### BACKGROUND ART

At present, memory devices have been necessarily applied to most electronic apparatus including personal computers. Such memory devices may be classified roughly into ROMs, such as electrically programmable read only memory (EPROM), electrically erasable PROM (EEPROM), flash ROM, etc., and RAMs, such as static random access memory (SRAM), dynamic RAM (DRAM), ferroelectric RAM (FRAM), etc. The memory device is fabricated generally by arranging capacitors and transistors on a semiconductor wafer.

In the conventional memory devices, various researches aimed mainly at increasing the density of memory cells have been made. However, non-volatile memory devices that can maintain data stored therein, even if the power supply is cut off have attracted attention recently. Accordingly, numerous researches aimed at using ferroelectric materials for such memory devices have continued to progress.

At present, as ferroelectric materials applied to the memory devices, inorganic compounds such as lead zirconate titanate (PZT), strontium bismuth tantalite (SBT), lanthanum-substituted bismuth titanate (BLT), etc. have been mainly used. However, such inorganic ferroelectrics have some drawbacks in that they are very expensive; the polarization characteristics may be deteriorated according to time; the formation of thin films requires a high temperature; and various expensive equipments are needed in using the inorganic ferroelectrics.

### DISCLOSURE

### Technical Problem

Accordingly, an object of the present invention is to provide a memory device, which can be readily manufactured at low cost by using organic materials having excellent polarization characteristics, and a method for manufacturing the same.

### Technical Solution

To accomplish the above object in accordance with a first aspect of the present invention, there is provided a ferroelectric memory device comprising: a substrate; a gate electrode; a drain electrode; a source electrode; a channel formation layer; and a ferroelectric layer, the ferroelectric layer being composed of a PVDF having a crystal structure of β-phase and the channel formation layer being arranged between the gate electrode and the ferroelectric layer.

Moreover, in accordance with a second aspect of the present invention, there is provided a ferroelectric memory device comprising: a substrate; a gate electrode; a drain electrode; a source electrode; a channel formation layer; and a ferroelectric layer, the ferroelectric layer being composed of a PVDF having a crystal structure of β-phase and the ferroelectric layer being arranged between the gate electrode and the channel formation layer.

The channel formation layer of the ferroelectric memory device is an organic semiconductor layer.

In addition, the channel formation layer of the ferroelectric memory device is an insulation layer.

Moreover, the substrate of the ferroelectric memory device is one selected from the group consisting of polyimide (PI), polycarbonate (PC), polyethersulfone (PES), polyetheretherketone (PEEK), polybutyleneterephthalate (PBT), polyethyleneterephthalate (PET), polyvinylchloride (PVC), polyethylene (PE), ethylene copolymer, polypropylene (PP), propylene copolymer, poly(4-methyl-1-pentene)(TPX), polyarylate (PAR), polyacetal (POM), polyphenyleneoxide (PPO), polysulfone (PSF), polyphenylenesulfide (PPS), polyvinylidenechloride (PVDC), polyvinylacetate (PVAC), polyvinylalcohol (PVA), polyvinylacetal (PVAL), polystyrene (PS), AS resin, ABS resin, polymethylmethacrylate (PMMA), fluorocarbon resin, phenol-formaldehyde (PF) resin, melamine-formaldehyde (MF) resin, urea-formaldehyde (UF) resin, unsaturated polyester (UP) resin, epoxy (EP) resin, diallylphthalate (DAP) resin, polyurethane (PUR), polyamide (PA), silicon (SI) resin and their mixtures and compounds.

The substrate of the ferroelectric memory device is made of materials including paper.

In addition, the insulation layer is made of an organic material.

Furthermore, in accordance with a third aspect of the present invention, there is provide a method for manufacturing a ferroelectric memory device comprising a substrate, a gate electrode, a drain electrode, a source electrode, a channel formation layer, and a ferroelectric layer, the method comprising the steps of: forming a gate electrode; forming a channel formation layer; forming a ferroelectric layer; forming drain and source electrodes; and phase-transitioning of the ferroelectric layer, where the ferroelectric layer is set to be of β-phase.

The channel formation layer is arranged between the gate electrode and the ferroelectric layer.

In addition, the ferroelectric layer is arranged between the gate electrode and the channel formation layer.

The step of phase-transitioning of the ferroelectric layer comprises: a first step of raising the temperature of the ferroelectric layer over a temperature, where a crystal structure of β-phase is established; a second step of lowering the temperature of the ferroelectric layer monotonously to the temperature, where the crystal structure of β-phase is established; and a third step of dropping the temperature of the ferroelectric layer rapidly.

In addition, the step of phase-transitioning of the ferroelectric layer comprises: a first step of raising the temperature of the ferroelectric layer over a temperature, where a crystal structure of β-phase is established; and a second step of dropping the temperature of the ferroelectric layer rapidly.

The ferroelectric layer is a PVDF layer.

Moreover, the step of phase-transitioning of the ferroelectric layer is executed after forming the gate electrode and the drain and source electrodes.

### DESCRIPTION OF DRAWINGS

The above and other features of the present invention will be described with reference to certain exemplary embodiments thereof illustrated the attached drawings in which:

FIG. 1 is a graph showing characteristics of a general PVDF;

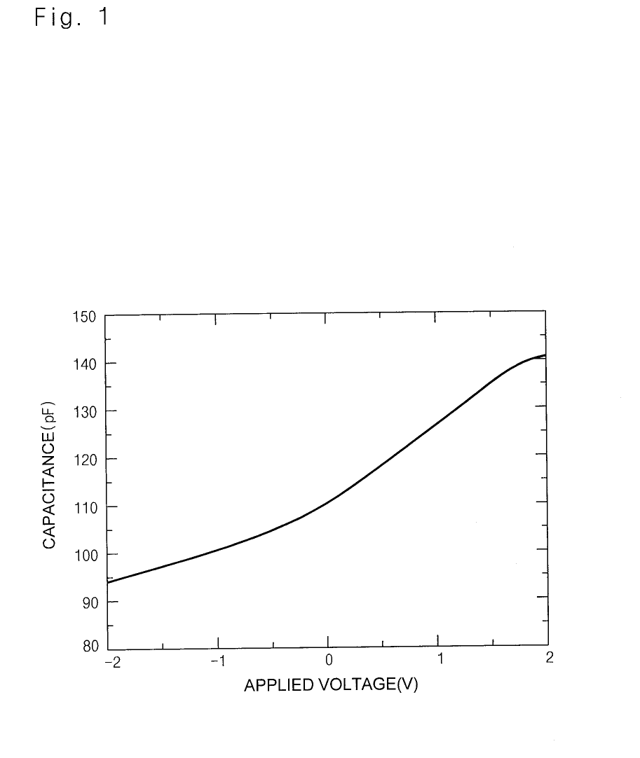

FIG. 2 is a graph depicting polarization characteristics of a PVDF, according to applied voltages, manufactured in accordance with the present invention;

FIG. 3 illustrates an exemplary configuration of a ferroelectric memory device in accordance with the present invention;

FIG. 4 is a diagram showing an equivalent circuit of the ferroelectric memory device in accordance with the present invention;

FIG. 5 is a diagram illustrating processes for manufacturing the ferroelectric memory device in accordance with the present invention; and

FIG. 6 depicts other exemplary configurations of the ferroelectric memory device in accordance with the present invention.

### BEST MODE FOR CARRYING OUT THE INVENTION

Hereinafter, the present invention will now be described more fully with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

First, the basic concept of the present invention will now be described.

At present, various kinds of organic materials having ferroelectric characteristics have been wide known. The typical organic materials may be exemplified by polyvinylidene fluoride (PVDF), PVDF polymer, PVDF copolymer or PVDF terpolymer and, further, odd-numbered nylon, cyano-polymer and their polymer or copolymer. Among such ferroelectric organic materials described above, PVDF, its polymer, copolymer and terpolymer have been mainly studied as organic semiconductor materials.

In general, to utilize such ferroelectric organic materials in manufacturing memory devices, corresponding organic materials should have hysteretic polarization characteristics for voltages applied. However, the PVDF described above shows an increased capacitance according to the applied voltages, and does not have the hysteresis characteristics.

According to the study results of the inventors of the present invention, it has been confirmed that the PVDF having four crystal structures of α, β, γ and δ shows a good hysteresis characteristic in the crystal structure of β-phase. Here, to crystallize the PVDF with β-phase, the PVDF is deposited on a semiconductor substrate and then cooled rapidly at a temperature, where phase transitions occur, e.g., 60 to 70° C., and preferably, about 65° C., or at a temperature, where the PVDF shows β-phases.

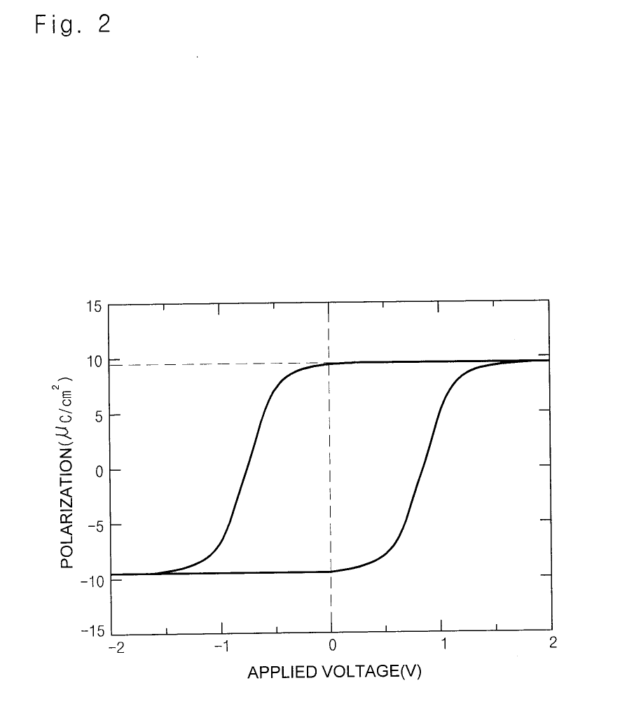

FIG. 2 is a graph depicting polarization characteristics of the PVDF thin film manufactured in accordance with the present invention, in which the measurement was made by applying a predetermined voltage between lower and upper electrodes made of conductive metal, between which the PVDF thin film of β-phase was formed. The PVDF thin film was formed in such a manner that after forming a PVDF of 1 μm or less on a lower electrode, for example, via a spin-coating process below 3,000 rpm and an annealing process above 120° C., the temperature of the PVDF thin film was monotonously lowered on a hot plate, and finally the PVDF thin film was cooled rapidly at 65° C., for example.

As can be seen in FIG. 2, the PVDF thin film manufactured in accordance with the present invention has excellent hysteresis characteristics that show a polarization of about 5 μC/cm² or more at about 1V as the polarization is increased with increasing of an applied voltage in about 0 to 1V, and show another polarization of about −5 μC/cm² or less at about −1V as the polarization is decreased with decreasing of an applied voltage in about 0 to −1V.

Accordingly, the PVDF thin film of the present invention has the following characteristics:

First, the PVDF thin film of the present invention shows a polarization above 5 μC/cm² or below −5 μC/cm² at 0V. This means that the polarization of the PVDF thin film is not changed but maintained at 0V, where no voltages are applied from the external. That is, the PVDF thin film in accordance with the present invention can be effectively used as a material of the non-volatile memory devices.

Second, the polarization of the PVDF thin film of the present invention is changed in a range of −1 to 1V. That is, it is possible to record and delete data at a very low voltage. Accordingly, the PVDF in accordance with the present invention can be effectively used in materializing the memory devices that operate at low voltages.

Next, the embodiments in accordance with the present invention will now be described more concretely.

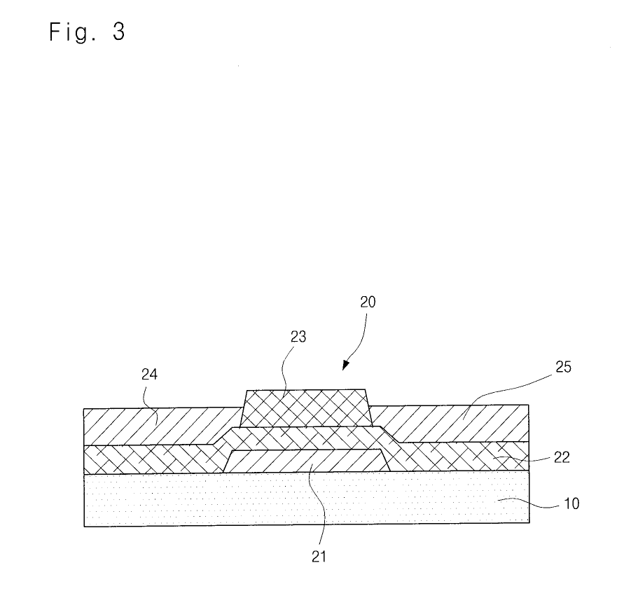

FIG. 3 illustrates a configuration of a ferroelectric memory device in accordance with a preferred embodiment of the present invention.

In the figure, a memory cell 20 is formed on a substrate 10. The substrate is made of silicon, metal and the like. Moreover, the substrate may be formed with organic materials such as paper coated with parylene or flexible plastic. Here, available organic materials may include polyimide (PI), polycarbonate (PC), polyethersulfone (PES), polyetheretherketone (PEEK), polybutyleneterephthalate (PBT), polyethyleneterephthalate (PET), polyvinylchloride (PVC), polyethylene (PE), ethylene copolymer, polypropylene (PP), propylene copolymer, poly(4-methyl-1-pentene) (TPX), polyarylate (PAR), polyacetal (POM), polyphenyleneoxide (PPO), polysulfone (PSF), polyphenylenesulfide (PPS), polyvinylidenechloride (PVDC), polyvinylacetate (PVAC), polyvinylalcohol (PVA), polyvinylacetal (PVAL), polystyrene (PS), AS resin, ABS resin, polymethylmethacrylate (PMMA), fluorocarbon resin, phenol-formaldehyde (PF) resin, melamine-formaldehyde (MF) resin, urea-formaldehyde (UF) resin, unsaturated polyester (UP) resin, epoxy (EP) resin, diallylphthalate (DAP) resin, polyurethane (PUR), polyamide (PA), silicon (SI) resin or their mixtures and compounds.

A gate electrode 21 as a lower electrode is formed on the substrate 10 via a well-known method. Such gate electrode 21 is made of aurum, argentum, aluminum, platinum, indium-tin oxide (ITO), strontium titanate (SrTiO₃); or conductive metal oxides, and their alloys and compounds; or mixtures, compounds or multilayer compounds, of which base are conductive polymers, such as polyaniline, poly(3,4-ethylenedioxythiophene)/polystyrenesulfonate (PEDOT:PSS), etc.

Subsequently, an organic semiconductor layer 22 as a channel formation layer is formed over the substrate 10 and the gate electrode 21. The organic semiconductor layer 22 may be formed with Cu-phthalocyanine, polyacetylene, merocyanine, polythiophene, phthalocyanine, poly(3-hexylthiophene), poly(3-alkylthiophene), α-sexithiophene, pentacene, α-ω-dihexyl-sexithiophene, polythienylenevinylene, bis(dithienothiophene), α-ω-dihexyl-quaterthiophene, dihexyl-anthradithiophene, α-ω-dihexyl-quinquethiophene, F8T2, Pc₂Lu, Pc₂Tm, C₆₀/C₇₀, TCNQ, C₆₀, PTCDI-Ph, TCNNQ, NTCDI, NTCDA, PTCDA, F16CuPc, NTCDI-C8F, DHF-6T, PTCDI-C8, etc.

Moreover, it is possible to use an insulation layer as the organic semiconductor layer 22 that is the channel formation layer. Such insulation layer may be formed with inorganic materials, such as ZrO₂, SiO₂, Y₂O₃, CeO₂, etc., or organic materials, such as BCB, polyimide, acryl, parylene C, PMMA, CYPE, etc.

The organic semiconductor layer 22 or the insulation layer is to form a channel of a ferroelectric memory device in accordance with the present invention.

A ferroelectric layer 23 is formed in the area corresponding to the gate electrode 21 on the organic semiconductor layer 22. Here, the ferroelectric layer 23 is established desirably with a PVDF having a crystal structure of β-phase.

Further, a drain electrode 24 and a source electrode 25 are arranged as upper electrodes on both sides of the ferroelectric layer 23.

Here, the drain electrode 24 and the source electrode 25 may be formed with aurum, argentum, aluminum, platinum, indium-tin oxide (ITO), strontium titanate (SrTiO₃); or conductive metal oxides, and their alloys and compounds; or mixtures, compounds or multilayer compounds, of which bases are conductive polymers, such as polyaniline, poly(3,4-ethylenedioxythiophene)/polystyrenesulfonate (PEDOT:PSS), etc.

In the above configuration, the ferroelectric layer 23 has polarization properties according to voltages applied to the gate electrode 21. The polarization properties by the ferroelectric layer 23 show polarizations of about 5 μC/cm² to −5 μC/cm² for the applied voltage in the range of −1 to 1V as described with reference to FIG. 2. Like this, according as a channel is established in the organic semiconductor layer 22 by the polarization properties of the ferroelectric layer 23, the drain electrode 24 and the source electrode 25 are set to be in a conduction state or a non-conduction state through the channel area.

Commonly used general memory devices have a basic structure of 1T-1C (one transistor-one capacitor). In such memory devices, data is recorded and read to and from a capacitor by charging or discharging a predetermined voltage to and from the capacitor via turning on/off a transistor in general.

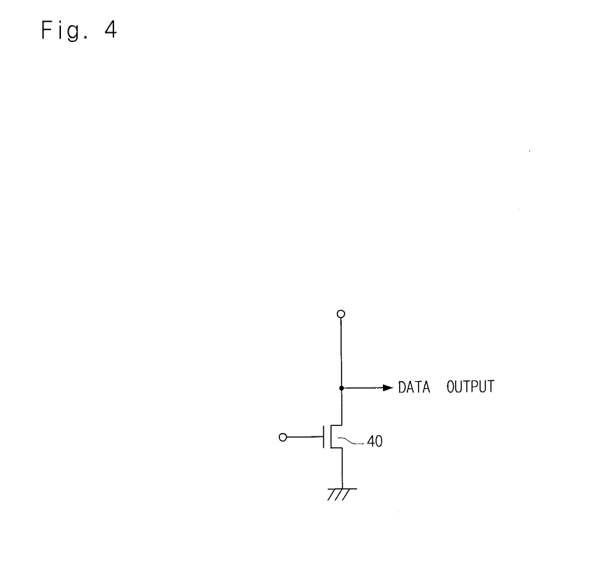

In the configuration of the present embodiment, the ferroelectric layer 23 has predetermined polarization properties according as voltages applied to the gate electrode 21 and the polarization properties are maintained uniformly even if the voltage is cut off. Accordingly, with the memory device in accordance with the present invention, it is possible to configure a non-volatile memory device with a simplified 1T structure, in which the source electrode of a memory device 40 is grounded and data is read from the drain electrode, as shown in FIG. 4.

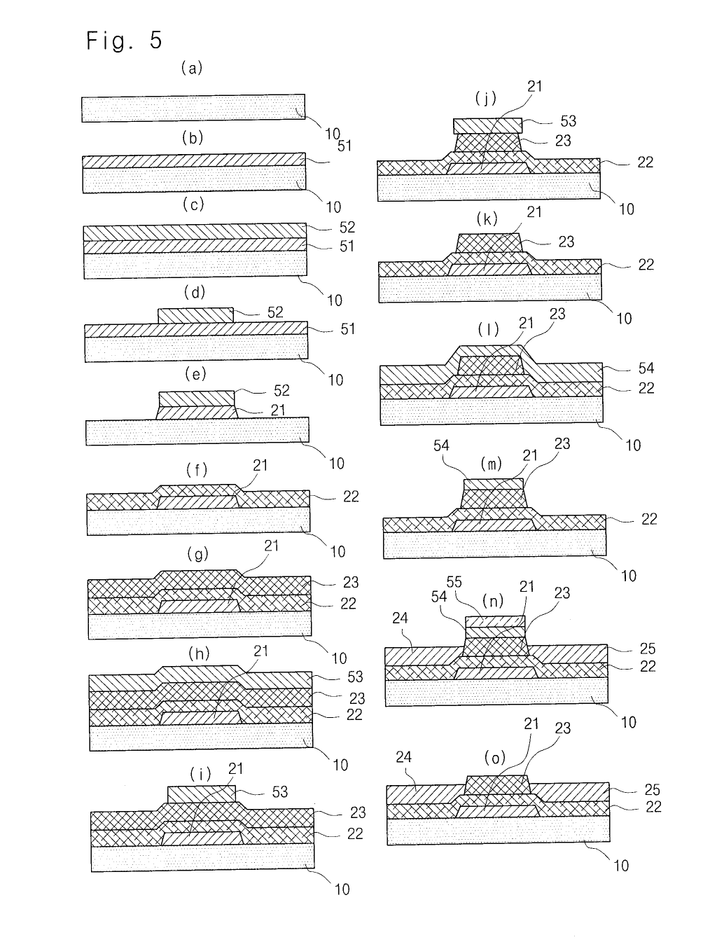

Continuously, the process for manufacturing the ferroelectric memory device in accordance with the present invention will now be described with reference to FIG. 5.

A conductive layer 51, such as aurum (AU), is deposited on a substrate 10, composed of semiconductor wafer, paper coated with parylene, or plastic (FIGS. 5a and 5b). Photoresist 52 is then spun via a spin-coating process (FIG. 5c).

Next, after removing the photoresist 52 except for the area for forming a gate electrode using a remover, such as acetone, the conductive layer 51 is etched based on the remaining photoresist as a mask to form a gate electrode 21 (FIGS. 5d and 5e).

After removing the photoresist 52 on the gate electrode 21, an inorganic or organic semiconductor layer 22 is formed over the entire surface on the substrate 10 via the spin-coating process (FIG. 5f), and a PVDF ferroelectric layer 23 is established on the semiconductor layer 22 (FIG. 5g). Here, in the process of forming the ferroelectric layer 23, the PVDF is crystallized with β-phase by rapidly cooling the PVDF at a temperature, where phase transitions occur, e.g., 60 to 70° C., and preferably, about 65° C., or at a temperature, where the PVDF shows β-phases.

Photoresist 53 is then spun via the spin-coating process (FIG. 5h) and the photoresist 53 except for the area corresponding to the gate electrode 21 is removed (FIG. 5i). Then, the ferroelectric layer 23 corresponding to the gate electrode 21 is removed using the photoresist 53 (FIG. 5j). The photoresist 53 formed on the ferroelectric layer 23 is also removed (FIG. 5k).

Repeatedly, photoresist 54 is formed via the same process as described above on the ferroelectric layer 23 (FIGS. 5l and 5m) . A conductive layer made of, for example, aurum is deposited over the resulting structure to form a drain electrode 24 and a source electrode 25 (FIG. 5n). Then, the photoresist 54 and the conductive layer 55 are removed via a lift-off process, thus fabricating a memory device (FIG. 5o).

In the above-described embodiment, a process for manufacturing a capacitor required for general memory devices is omitted. Accordingly, it is possible to simplify the manufacturing process and increase the number of memory devices fabricated in a fixed area sharply.

Meanwhile, in the above embodiment, after forming the ferroelectric layer 23, i.e., the PVDF layer, the crystal structure of the PVDF layer is formed with β-phase by rapidly cooling the substrate 10 at a temperature, where the PVDF shows β-phases.

In case where the memory devices are manufactured via such a manner, the crystal structure of the ferroelectric layer 23 may be changed due to heat applied to the substrate 10 when fabricating the drain electrode 24 and the source electrode 25 after forming the ferroelectric layer 22.

Accordingly, it is desirable that the crystal structure of the ferroelectric layer 23 is set after completing all processes for fabricating the memory device, not setting the crystal structure of the ferroelectric layer 23 immediately after forming the ferroelectric layer 23. That is, it is desirable that the crystal structure of the ferroelectric layer 23 is set in such a manner that the structure, after forming the drain electrode 24 and the source electrode 25, is heated over a temperature, where the ferroelectric layer 23 shows β-phases, and cooled monotonously to the temperature, where the β-phases are shown, or the structure is heated to a temperature, where the ferroelectric layer 23 shows β-phases, and cooled rapidly.

Although the present invention has been described with reference to certain exemplary embodiments thereof, it will be understood by those skilled in the art that a variety of modifications may be made therein without departing from the spirit or scope of the present invention defined by the appended claims and their equivalents.

For example, the preferred embodiment is described citing an instance, where the gate electrode 21 is coupled with the ferroelectric layer 23 via the organic semiconductor layer 22.

However, applying various configurations other than the above configuration can materialize the ferroelectric memory device in accordance with the present invention.

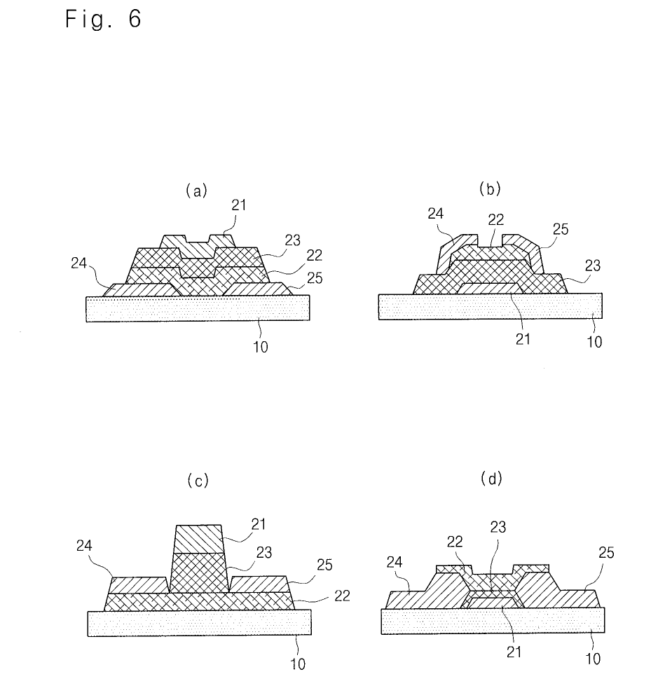

FIG. 6 depicts other exemplary configurations of the ferroelectric memory device in accordance with the present invention, wherein the gate electrode 21 and the ferroelectric layer 23 are connected directly with each other and the organic semiconductor layer 22 is formed on the opposite side to the gate electrodes 21 based on the ferroelectric layer 23. FIG. 6a depicts a staggered structure; FIG. 6b depicts an inverted staggered structure; FIG. 6c depicts a coplanar structure; and FIG. 6d depicts an inverted coplanar structure. Moreover, like elements in FIG. 6 have the same reference numerals as FIG. 3.

In the configurations shown in FIG. 6, if applying a predetermined voltage to the gate electrode 21, the polarization is caused in the ferroelectric layer 23, thus forming a channel in the organic semiconductor layer 22. And through the channel formed like this, the drain electrode 24 and the source electrode 25 is set to be in a conduction state or a non-conduction state.

Furthermore, it is possible to use an insulation layer instead of the organic semiconductor layer 22. That is, any layers, as such organic semiconductor layer, are available if they can form a channel according to the voltage applied thereto.

In addition, the preferred embodiment is described citing an instance, where the present invention is applied to the inverted staggered structure; however, it is possible to apply the present invention to the staggered structure, the coplanar structure, and the inverted coplanar structure as well.

### INDUSTRIAL APPLICABILITY

According to the present invention using organic materials as ferroelectric materials, it is possible to manufacture memory devices more readily than the other conventional ferroelectric memory devices using inorganic materials and to reduce the manufacturing cost. Moreover, since the PVDF having a crystal structure of β-phase in accordance with the present invention shows polarization properties at a low voltage, it is possible to materialize a non-volatile memory that operates at a very low voltage.

1. A ferroelectric memory device comprising:
a substrate; a gate electrode; a drain electrode; a source electrode; a channel formation layer; and a ferroelectric layer, the ferroelectric layer being composed of a PVDF having a crystal structure of β-phase and the channel formation layer being arranged between the gate electrode and the ferroelectric layer.

2. The ferroelectric memory device as recited in claim 1, wherein the channel formation layer is an organic semiconductor layer.

3. The ferroelectric memory device as recited in claim 1, wherein the channel formation layer is an insulation layer.

4. The ferroelectric memory device as recited in claim 1, wherein the substrate is one selected from the group consisting of polyimide (PI), polycarbonate (PC), polyethersulfone (PES), polyetheretherketone (PEEK), polybutyleneterephthalate (PBT), polyethyleneterephthalate (PET), polyvinylchloride (PVC), polyethylene (PE), ethylene copolymer, polypropylene (PP), propylene copolymer, poly(4-methyl-1-pentene) (TPX), polyarylate (PAR), polyacetal (POM), polyphenyleneoxide (PPO), polysulfone (PSF), polyphenylenesulfide (PPS), polyvinylidenechloride (PVDC), polyvinylacetate (PVAC), polyvinylalcohol (PVA), polyvinylacetal (PVAL), polystyrene (PS), AS resin, ABS resin, polymethylmethacrylate (PMMA), fluorocarbon resin, phenol-formaldehyde (PF) resin, melamine-formaldehyde (MF) resin, urea-formaldehyde (UF) resin, unsaturated polyester (UP) resin, epoxy (EP) resin, diallylphthalate (DAP) resin, polyurethane (PUR), polyamide (PA), silicon (SI) resin and their mixtures and compounds.

5. The ferroelectric memory device as recited in claim 1, wherein the substrate is made of materials including paper.

6. The ferroelectric memory device as recited in claim 1,
wherein the insulation layer is made of an organic material.

7. A ferroelectric memory device comprising:
a substrate; a gate electrode; a drain electrode; a source electrode; a channel formation layer; and a ferroelectric layer, the ferroelectric layer being composed of a PVDF having a crystal structure of β-phase and the ferroelectric layer being arranged between the gate electrode and the channel formation layer.

8. The ferroelectric memory device as recited in claim 7, wherein the channel formation layer is an organic semiconductor layer.

9. The ferroelectric memory device as recited in claim 7, wherein the channel formation layer is an insulation layer.

10. The ferroelectric memory device as recited in claim 7,
wherein the substrate is one selected from the group consisting of polyimide (PI), polycarbonate (PC), polyethersulfone (PES), polyetheretherketone (PEEK), polybutyleneterephthalate (PBT), polyethyleneterephthalate (PET), polyvinylchloride (PVC), polyethylene (PE), ethylene copolymer, polypropylene (PP), propylene copolymer, poly(4-methyl-1-pentene) (TPX), polyarylate (PAR), polyacetal (POM), polyphenyleneoxide (PPO), polysulfone (PSF), polyphenylenesulfide (PPS), polyvinylidenechloride (PVDC), polyvinylacetate (PVAC), polyvinylalcohol (PVA), polyvinylacetal (PVAL), polystyrene (PS), AS resin, ABS resin, polymethylmethacrylate (PMMA), fluorocarbon resin, phenol-formaldehyde (PF) resin, melamine-formaldehyde (MF) resin, urea-formaldehyde (UF) resin, unsaturated polyester (UP) resin, epoxy (EP) resin, diallylphthalate (DAP) resin, polyurethane (PUR), polyamide (PA), silicon (SI) resin and their mixtures and compounds.

11. The ferroelectric memory device as recited in claim 7, wherein the substrate is made of materials including paper.

12. The ferroelectric memory device as recited in claim 7, wherein the insulation layer is made of an organic material.

13. In a method for manufacturing a ferroelectric memory device comprising a substrate, a gate electrode, a drain electrode, a source electrode, a channel formation layer, and a ferroelectric layer, the method comprising the steps of:
forming a gate electrode;
forming a channel formation layer;
forming a ferroelectric layer;
forming drain and source electrodes; and
phase-transitioning of the ferroelectric layer, where the ferroelectric layer is set to be of β-phase.

14. The method for manufacturing a ferroelectric memory device as recited in claim 13,
wherein the channel formation layer is arranged between the gate electrode and the ferroelectric layer.

15. The method for manufacturing a ferroelectric memory device as recited in claim 13,
wherein the ferroelectric layer is arranged between the gate electrode and the channel formation layer.

16. The method for manufacturing a ferroelectric memory device as recited in claim 13,
wherein the step of phase-transitioning of the ferroelectric layer comprises:
a first step of raising the temperature of the ferroelectric layer over a temperature, where a crystal structure of β-phase is established;
a second step of lowering the temperature of the ferroelectric layer monotonously to the temperature, where the crystal structure of β-phase is established; and
a third step of dropping the temperature of the ferroelectric layer rapidly.

17. The method for manufacturing a ferroelectric memory device as recited in claim 13,
wherein the step of phase-transitioning of the ferroelectric layer comprises:
a first step of raising the temperature of the ferroelectric layer over a temperature, where a crystal structure of β-phase is established; and
a second step of dropping the temperature of the ferroelectric layer rapidly.

18. The method for manufacturing a ferroelectric memory device as recited in claim 13,
wherein the ferroelectric layer is a PVDF layer.

19. The method for manufacturing a ferroelectric memory device as recited in claim 13,
wherein the step of phase-transitioning of the ferroelectric layer is executed after forming the gate electrode and the drain and source electrodes.
